(19) United States
(12) Patent Application Publication
(10) Pub. No.: US 2019/0140046 A1
(43) Pub. Date: May 9, 2019

(54) SILICON CARBIDE POWER DEVICE EMPLOYING HETEROJUNCTION TERMINAL AND MANUFACTURING METHOD THEREOF

(71) Applicant: XIAMEN SANAN INTEGRATED CIRCUIT CO., LTD., Xiamen (CN)

(72) Inventors: Cheng LIU, Xiamen (CN); Nien-Tze YEH, Xiamen (CN); Hou-Kuei HUANG, Xiamen (CN)

(73) Assignee: XIAMEN SANAN INTEGRATED CIRCUIT CO., LTD., Xiamen (CN)

(21) Appl. No.: 16/236,806

(22) Filed: Dec. 31, 2018

Related U.S. Application Data
(63) Continuation of application No. PCT/CN2017/090512, filed on Jun. 28, 2017.

(30) Foreign Application Priority Data
Jul. 11, 2016 (CN) 201610541460.4

(51) Int. Cl. H01L 29/06; H01L 29/872; H01L 29/861; H01L 29/267; H01L 29/66

(52) U.S. Cl. CPC H01L 29/0619; H01L 29/872; H01L 29/1608; H01L 29/267; H01L 29/6606; H01L 29/8611

(57) ABSTRACT

A Silicon Carbide (SiC) power device employing a heterojunction terminal includes: a cathode electrode, a substrate layer, an N-type SiC extension layer, an anode electrode, and a plurality of P-type structures disposed at interval. The plurality of P-type structures grow and form, via a heterogeneous epitaxy, using a P-type semiconductor material having a growth temperature less than that of SiC, and on the N-type SiC extension layer, and are evenly or unevenly distributed at periphery of the anode electrode, so as to form a heterogeneous terminal. Therefore, the embodiment effectively prevents impact on a doping characteristic of the N-type SiC extension layer, and can obtain a SiC device having a high breakdown voltage and low device turn-on voltage. Also provided is a manufacturing method of the SiC power device. The embodiment reduces requirements for a high-temperature or complex technique, provides a simple process, and reduces manufacturing costs.

### CROSS-REFERENCE TO RELATED APPLICATIONS

The present application is a continuation of, and claims priority to, PCT/CN2017/090512 filed on Jun. 28, 2017, which claims priority to Chinese Patent Application No. 201610541460.4 filed on Jul. 11, 2016. The disclosures of these applications are hereby incorporated by reference in their entirety.

### BACKGROUND

Power devices based on wide-forbidden band (such as silicon carbide (SiC) and gallium nitride (GaN)) are expected to be widely applied in next-generation electric power generation thanks to high breakdown voltage and power density. In SiC power devices, electrical field are often crowded in the junction edge due to discontinuity of junction, resulting in high electric field at the junction edge. The high electric field will cause early breakdown of the junction edge, which greatly limits the device reverse breakdown voltage. Therefore, various junction terminal technologies are often used to mitigate the local electric field crowding effect during design and manufacturing of SiC power devices and to improve device breakdown voltage. Most Commonly used junction terminal technologies include guard ring, junction terminal extension and field plate structure. The guard ring and junction terminal extension requiring no high-quality dielectric materials that are widely applied in the manufacturing of devices. SiC power devices are often based on the N-type SiC substrate and the weak N-type epitaxy layer as the drift region. Correspondingly, the P-type SiC is taken as the junction terminal to form a depletion region for alleviating electrical field at the junction edge.

### SUMMARY

The inventors of the present disclosure have recognized that, the P-type SiC region can be manufactured by epitaxy growth and ion implantation. Epitaxial growth means to directly grow P-type SiC over the entire surface of the N-type SiC layer. As growth temperature of the P-type SiC is generally high (>1,500° C.), some P-type impurities (such as Al) are inevitably diffused into weak N-type SiC during growth. This results in self-doping over the N-type SiC surface, and even transforms the region into P-type, thus changing the doping characteristics of the N-type SiC surface and influencing the obtaining of low turn-on voltage of power devices. P-type ion implantation for SiC often requires advanced equipment such as high-temperature ion implanter and ultra-high temperature annealing furnace, which restraints the widely adoption by industry due to complex process and high cost.

Various embodiments of the present disclosure provide a SiC power device with a heterojunction terminal and manufacturing method thereof to overcome the technical drawback of the prior art.

Various approaches can be adopted in the present disclosure to solve the technical problems. For example, a SiC power device with a heterojunction terminal comprises from bottom to up a cathode electrode, a substrate layer, an N-type SiC epitaxial layer and an anode electrode, and also comprises a plurality of separated P-type structures, in which, these P-type structures are formed over the N-type SiC epitaxial layer by P-type semiconductor material with growth temperature lower than SiC, which at least are distributed in the anode electrode periphery to form a heterojunction terminal.

In some embodiments, growth temperature the P-type semiconductor material is 600° C.-1,200° C.

In some embodiments, the P-type semiconductor material is P-type GaN or P-type AlGaN.

In some embodiments, the P-type structures comprise a plurality of closed ring structures surrounding the anode electrode periphery, and the closed ring structures are arranged at equidistant or unequal spacing.

In some embodiments, at least part of the anode electrode and the N-type SiC epitaxial layer form Schottky contact.

In some embodiments, the P-type structures also comprise a plurality of separate structures between the anode electrode and the N-type SiC epitaxial layer.

In some embodiments, the P-type structures also comprise a plurality of layered structures between the anode electrode and the N-type SiC epitaxial layer that separate the anode electrode and the N-type SiC epitaxial layer.

In some embodiments, the upper surface of the N-type SiC epitaxial layer is provided with a plurality of grooves, and the P-type structures are formed inside the grooves correspondingly.

In some embodiments, a dielectric layer is provided, wherein, the dielectric layer is arranged over the N-type SiC epitaxial layer and covers the region beyond the anode electrode and the P-type structures in the region.

In some embodiments, the dielectric layer is any one of or a combination of SiNₓ, SiO₂, Al₂O₃, AlN, wherein, 0<X<1.

A method for manufacturing the SiC power device is provided, comprising:

(1) providing a SiC epitaxial structure, comprising stacked layers of substrate layer and an N-type SiC epitaxial layer;

(2) growing P-type semiconductor material over the N-type SiC epitaxial layer via heteroepitaxial growth, and defining a plurality of separated P-type structures, wherein, the heteroepitaxial growth includes chemical vapor deposition and molecular beam epitaxy, and growth temperature of the P-type semiconductor material is lower than that of SiC; and

(3) manufacturing an anode electrode and a cathode electrode at both sides of the structure in step 2).

In some embodiments, form a plurality of P-type structures via selective epitaxial growth through patterned mask, defined by dry etching or wet etching in step 2).

In some embodiments, deposit a dielectric layer and etch the window opening over the structure obtained in step 2), and manufacture an anode electrode over the window opening in step 3).

In some embodiments, form the anode electrode and the cathode electrode by depositing metals via electron beam deposition, magnetron sputtering, ion evaporation or arc ion evaporation in step 3), and form Schottky contact or ohmic contact via annealing.

Embodiments of the present disclosure can have one or more of the following advantages.

1. A plurality of P-type structures are formed over the N-type SiC epitaxial layer, which are at least distributed in the anode electrode periphery to form a junction terminal structure for alleviating electrical field at the junction edge. These P-type structures are formed by heteroepitaxial of P-type semiconductor materials with growth temperature lower than SiC growth temperature. Due to low growth temperature and different doping mechanism, this effectively prevents from affecting doping characteristics of the N-type SiC epitaxial layer, thus obtaining a high-performance SiC device with high breakdown voltage and low turn-on voltage. In addition, this method greatly reduces requirements for high temperature or complex process and features simple process and low manufacturing costs.

2. The structure is applicable for Schottky barrier diode (SBD), junction barrier Schottky diode (JBS) and PN junction diode. In the latter two structures, the P-type doping region between the anode electrode and the N-type SiC epitaxial layer can also be formed with the junction terminal structure at the same time, which can be widely applied with simple process.

### BRIEF DESCRIPTION OF THE DRAWINGS

FIG. 1 is a structural schematic diagram according to Embodiment 1.

FIG. 2 is a structural schematic diagram according to Embodiment 2.

FIG. 3 is a structural schematic diagram according to Embodiment 3.

### DETAILED DESCRIPTION

The present disclosure will be explained in details with reference to the accompanying drawings and embodiments. The drawings are only for illustration and better understanding of the present invention. The specific scale can be adjusted based on design requirements. Those skilled in the art should understand that the upper and lower positions as illustrated in the drawings are merely referred to relative positions of the components, which can be flipped to show same components, which should be also fallen into the scope of this specification. In addition, the number of components and structures illustrated in the diagram are only exemplary, which cannot be interpreted as limiting, which can be adjusted based on actual requirements.

### Embodiment 1

With reference to FIG. 1, the SiC power device according to the present embodiment is a SiC Schottky barrier diode (SBD) 100, comprising from bottom to up a cathode electrode 110, a substrate layer 120, an N-type SiC epitaxial layer 130 and an anode electrode 140, wherein, the anode electrode 140 and the N-type SiC epitaxial layer 130 form metal-semiconductor Schottky contact. A plurality of P-type structures 150 are formed in the periphery of the anode electrode 140 over the N-type SiC epitaxial layer 130 to form a junction terminal. Outside the anode electrode 140 region, the exposed N-type SiC epitaxial layer 130 and the P-type structure 150 are covered with a dielectric layer 160.

The P-type structure 150 is directly formed over the N-type SiC epitaxial layer 130 by heteroepitaxial grown of P-type semiconductor material with growth temperature lower than that of the SiC. Specifically, growth temperature of the P-type semiconductor material is 600° C.-1,200° C., and the P-type semiconductor material can be P-type GaN or P-type AlGaN. Taking P-type GaN as an example, growth temperature of P-type GaN is about 700° C., and growth temperature of SiC is usually above 1,500° C. Under such temperature, the P-type doping impurities will not diffuse into the N-type SiC epitaxial layer 130, causing no effects on doping characteristics of the N-type SiC epitaxial layer 130, thus maintaining characteristics and achieving good overall performance of the device. Further, doping concentration of the N-type SiC epitaxial layer 130 is <5×10¹⁶/cm³, and doping concentration of the P-type semiconductor material is >5×10¹⁷/cm³, and the P-type structure 150 has a depletion region for alleviating electrical field at the junction edge. Compared with P-type SiC (>1×10¹⁸/cm³), the P-type semiconductor obtained by heteroepitaxial growth can have same effects with even low doping concentration.

In some embodiments, the P-type structures 150 are a plurality of closed ring structures surrounding the periphery of the anode electrode 140, and the closed ring structures are arranged at equidistant or unequal spacing. The arrangement of the closed ring structures can effectively avoid early breakdown of the device caused by highly concentrated electronic field at the SiC main junction. Under high-voltage blocking status, the depletion region is formed in the main junction and extends outwards. Once horizontal extension of the depletion region along the SiC surface touches the closed ring 150 region, the P-type closed ring will sense a potential. The closed ring potential can effectively help further extension of the depletion region, and avoid electronic field concentration due to narrow depletion region. Further, the sizes of these closed rings, including thickness, width and spacing, are determined based on voltage rating of actual device (such as thickness of 130). For 600-1,200 V voltage-rated devices, thickness of the N-type SiC epitaxial layer 130 is 4-12 μm, and thickness of the corresponding closed ring of the P-type structure 150 is 200-800 nm, and the width can be 0.5-10 μm, and spacing can be 1-10 μm.

The dielectric layer 160 covers the region beyond the anode electrode 140 above the diode structure to alleviate electronic field and effectively increase breakdown voltage. In some embodiments, the medium layer 160 is any one or a combination of SiNₓ, SiO₂, Al₂O₃, AlN, where, 0<X<1.

In the diode of the embodiment, the substrate is preferred to be a homogeneous SiC substrate, and the anode electrode and the cathode electrode are such metals as Ti, Ni, Pt, Al, Ag, Au, W, Pb and Si as well as their alloys or laminated composites.

The manufacturing method is described below taking the P-type structure of GaN as an example. At first, provide a SiC epitaxial structure, comprising stacked layers of a substrate layer and an N-type SiC epitaxial layer. Grow a P-type GaN layer over the N-type SiC epitaxial layer via chemical vapor deposition method, taking trimethyl gallium (TMGa), trimethylaluminum (TMAl) and ammonia as the Ga source, the Al source and the N source, and the bis(cyclopentadienyl)magnesium (Cp₂Mg) as the P-type doping source. Decompose the gas under 700° C. and deposit a P-type GaN layer over the N-type SiC epitaxial layer, and define a plurality of separate P-type structures via dry etching (such as ICP or RIE) of the P-type GaN layer. In this embodiment, the P-type structures are a plurality of closed ring structures; next, deposit a dielectric layer over the surface of the epitaxial structure via chemical vapor deposition, atomic layer deposition, sputtering and etch windows opening through it; deposit metals at the backside of the substrate layer via electron beam deposition, magnetron sputtering, ion evaporation or arc ion evaporation, which is In some embodiments made of Ti/Ni, and anneal the back metal layer for 2 minutes under 1,000° C. to form ohmic contact; finally, deposit metals over the etching windows of the dielectric layer via electron beam deposition, magnetron sputtering, ion evaporation or arc ion evaporation to manufacture an anode electrode, which is preferred to be Ti/Ni, and anneal the anode metal layer for 5 minutes under 550° C. to form Schottky contact. The anode electrode can be thicker than the dielectric layer and covers some parts surrounding the upper surface of the dielectric layer.

In addition, the P-type semiconductor material can also be grown via metal organic vapor phase deposition or molecular beam epitaxy, and the patterning can be realized by selective growth, such as epitaxy through a patterned dielectric mask obtained by photolithography and wet etching.

### Embodiment 2

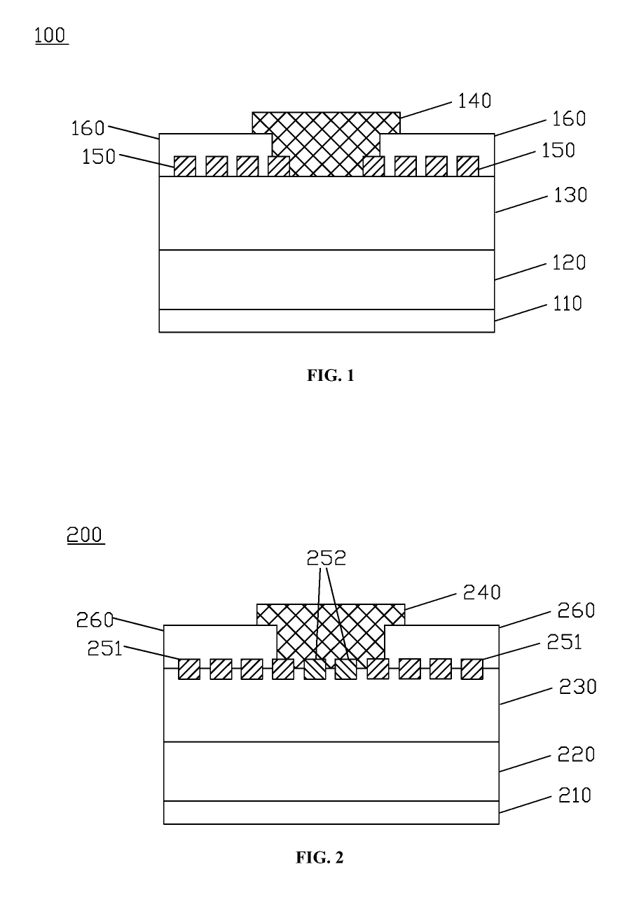

With reference to FIG. 2, the SiC power device according to the present embodiment is a SiC junction barrier Schottky diode 200. The difference between this embodiment and Embodiment 1 is that: in addition to the P-type structures 251 distributed in the periphery of anode electrode 240 over the N-type SiC epitaxial layer 230, which forms a heterojunction terminal, the P-type structure also comprises a plurality of P-type structures 252 formed between the anode electrode 240 and the N-type SiC epitaxial layer 230, which forms a junction barrier. Specifically, the P-type structure 252 can be a plurality of parallel strip structures, which form a plurality of laterally distributed PN junctions between the N-type SiC epitaxial layer 230 and P-type structure 252, while the exposed N-type SiC epitaxial layer 230 and the anode electrode 240 between adjacent P-type structures 252 form Schottky junction. Under reverse blocking state, blocking characteristics similar to the PN diode can be gained via the pinch-off effect induced by the depletion region extension of adjacent PN junctions; under forward conducting status, the Schottky junction with low barrier height starts to turn on first with conducting characteristics similar to the Schottky diode.

The upper surface of the N-type SiC epitaxial layer 230 is provided with a plurality of grooves 231, and these P-type structures 251 and 252 are formed in the grooves correspondingly. Through contacting the N-type SiC sidewall at a certain groove depth, the PN junction is constructed at the etched SiC surface as well as in the inner side, which effectively reduces reverse leakage current without compromising the forward turn-on voltage. Other structures, such as the cathode electrode 210, the substrate layer 220 and the dielectric layer 160, can be referred to Embodiment 1.

Compared with Embodiment 1, the manufacturing method according to the present embodiment also includes etching the upper surface of the N-type SiC epitaxial layer to form aforesaid grooves before forming the P-type structure. The junction barrier structure and the junction terminal structure are formed at the same time. In some embodiments, the P-type structures 251 are closed ring, and the P-type structures 252 are strip-shaped, which are patterned via etching or selective epitaxy.

### Embodiment 3

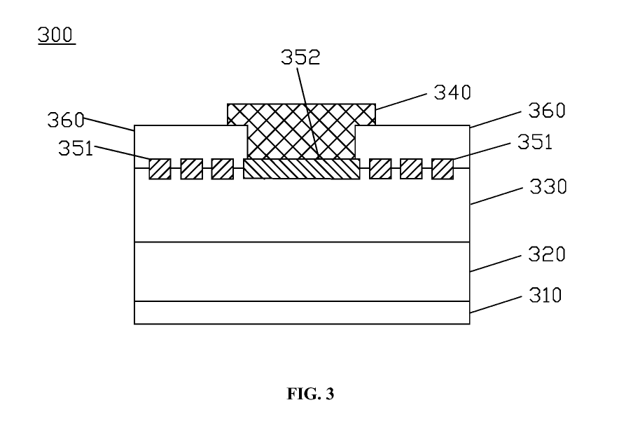

With reference to FIG. 3, the SiC power device of the embodiment is a SiC PN junction diode 300. The difference between this embodiment and Embodiment 2 is that, in addition to the P-type structures 351 distributed at the periphery of anode electrode 340 over the N-type SiC epitaxial layer 330, which forms a heterojunction terminal, the P-type structure also comprises a plurality of layered P-type structures 352, which are arranged between the anode electrode 340 and the N-type SiC epitaxial layer 330 that separate the anode electrode 340 and the N-type SiC epitaxial layer 330. Moreover, a PN junction is formed between the P-type structure 352 and the N-type SiC epitaxial layer 330. Other structures, such as the cathode electrode 310, the substrate layer 320 and the dielectric layer 360, can be referred to Embodiment 1, and the manufacturing method can be referred to Embodiment 2, which are not described again.

The aforesaid embodiments are merely used for further description of a SiC power device with a heterojunction terminal and manufacturing method thereof according to the present invention. It should be understood that any simple variations, equivalent changes or modifications will fall within the scope of the disclosures without departing from the substantive features of the invention.

1. A SiC power device comprising:
a cathode electrode;
a substrate layer disposed over the cathode electrode;
an N-type SiC epitaxial layer disposed over the substrate layer;
an anode electrode disposed over the N-type SiC; and
a plurality of separated P-type structures formed over the N-type SiC epitaxial layer by P-type semiconductor material with a growth temperature lower than SiC, and at least distributed in a periphery of the anode electrode to form a heterojunction terminal.

2. The SiC power device of claim 1, wherein a growth temperature of the P-type semiconductor material is 600° C.-1200° C.

3. The SiC power device of claim 2, wherein the P-type semiconductor material is P-type GaN or P-type AlGaN.

4. The SiC power device of claim 1, wherein the P-type structures comprise a plurality of closed ring structures surrounding the anode electrode periphery, and the closed ring structures are arranged at equidistant or unequal spacing.

5. The SiC power device of claim 4, wherein at least a portion of the anode electrode and the N-type SiC epitaxial layer form Schottky contact.

6. The SiC power device with a heterojunction terminal of claim 5, wherein the P-type structures also comprise a plurality of separate structures between the anode electrode and the N-type SiC epitaxial layer.

7. The SiC power device of claim 1, wherein at least a portion of the anode electrode and the N-type SiC epitaxial layer form Schottky contact.

8. The SiC power device with a heterojunction terminal of claim 4, wherein: the P-type structures also comprise a plurality of layered structures between the anode electrode and the N-type SiC epitaxial layer that separate the anode electrode and the N-type SiC epitaxial layer.

9. The SiC power device with a heterojunction terminal of claim 1, wherein: the P-type structures also comprise a plurality of layered structures between the anode electrode and the N-type SiC epitaxial layer that separate the anode electrode and the N-type SiC epitaxial layer.

10. The SiC power device of claim 1, wherein: the upper surface of the N-type SiC epitaxial layer is provided with a plurality of grooves, and the P-type structures are formed inside the grooves correspondingly.

11. The SiC power device of claim 1, wherein: a dielectric layer is provided, wherein, the dielectric layer is arranged over the N-type SiC epitaxial layer and covers the region beyond the anode electrode and the P-type structures in the region.

12. The SiC power device with a heterojunction terminal of claim 11, wherein:
the dielectric layer comprises at least one of SiNₓ, SiO₂, Al₂O₃, or AlN; and 0<X<1.

13. A method of manufacturing the SiC power device of claim 1, the method including:
(1) providing a SiC epitaxial structure, comprising the substrate layer and the N-type SiC epitaxial layer;
(2) growing a P-type semiconductor material over the N-type SiC epitaxial layer via heteroepitaxial growth, and defining the plurality of separated P-type structures, wherein, the heteroepitaxial growth includes at least one of a chemical vapor deposition or a molecular beam epitaxy, and the growth temperature of the P-type semiconductor material is lower than that of SiC; and
(3) manufacturing the anode electrode and the cathode electrode at both sides of the structure in step 2).

14. The manufacturing method of claim 13, wherein: forming a plurality of P-type structures by selective epitaxial growth through a mask, dry etching or wet etching in step 2).

15. The manufacturing method of claim 13, wherein: depositing a dielectric layer and etching the open window over the structure obtained in step 2), and manufacturing an anode electrode over the open window in step 3).

16. The manufacturing method of claim 15, wherein step (3) comprises depositing metals via electron beam evaporation, magnetron sputtering, ion evaporation or arc ion evaporation, and forming Schottky contact or ohmic contact via annealing.

17. The manufacturing method of claim 13, wherein: forming the anode electrode and the cathode electrode by depositing metals via electron beam evaporation, magnetron sputtering, ion evaporation or arc ion evaporation in step 3), and forming Schottky contact or ohmic contact via annealing.
